(19) United States
(12) Patent Application Publication
(10) Pub. No.: US 2004/0075163 A1
(43) Pub. Date: Apr. 22, 2004

(54) Semiconductor device and method of manufacturing the same, circuit board, and electronic instrument

(75) Inventor: Hirohisa Nakayama, Sakata-shi (JP)

Correspondence Address: OLIFF & BERRIDGE, PLC, P.O. BOX 19928, ALEXANDRIA, VA, 22320, US

(73) Assignee: Seiko Epson Corporation, Tokyo (JP)

(21) Appl. No.: 10/615,846

(22) Filed: Jul. 10, 2003

(30) Foreign Application Priority Data
Jul. 25, 2002 (JP) 2002-216657

(51) Int. Cl. H01L 21/44; H01L 23/02; H01L 21/461; H01L 21/50

(52) U.S. Cl. 257/678; 438/106; 438/118; 438/123; 438/124; 438/690

(57) ABSTRACT

A semiconductor device having a semiconductor chip, a sheet on which is mounted the semiconductor chip, a sealing section in which the semiconductor chip and the sheet are sealed, and a plurality of leads electrically connected to the semiconductor chip by wires in the sealing section. The leads include a first lead to which the sheet is bonded and a second lead to which the sheet is not bonded.

Japanese Patent Application No. 2002-216657 filed on Jul. 25, 2002, is hereby incorporated by reference in its entirety.

### BACKGROUND OF THE INVENTION

The present invention relates to a semiconductor device and a method of manufacturing the same, a circuit board, and an electronic instrument.

In a semiconductor device using a lead frame, a semiconductor chip is mounted on a die pad and sealed with a resin. The external shape of the die pad is designed corresponding to the external shape of the semiconductor chip. Therefore, it is necessary to manufacture the lead frames corresponding to different external shapes of the semiconductor chips, whereby time and cost are increased. Moreover, since the die pad (metal) has inferior adhesion to the sealing resin, the sealing resin may be removed from the die pad.

### BRIEF SUMMARY OF THE INVENTION

According to a first aspect of the present invention, there is provided a semiconductor device comprising:

a semiconductor chip;

a sheet on which the semiconductor chip is mounted;

a sealing section in which the semiconductor chip and the sheet are sealed; and

a plurality of leads electrically connected to the semiconductor chip by wires within the sealing section,

wherein the leads include a first lead which is bonded to the sheet and a second lead which is not bonded to the sheet.

According to a second aspect of the present invention, there is provided a circuit board on which is mounted the above semiconductor device.

According to a third aspect of the present invention, there is provided an electronic instrument comprising the above semiconductor device.

According to a fourth aspect of the present invention, there is provided a method of manufacturing a semiconductor device comprising:

bonding a sheet to a lead frame including first and second leads;

mounting a semiconductor chip on the sheet;

electrically connecting the semiconductor chip to the first and second leads by wires; and

sealing the semiconductor chip and the sheet in,

wherein the first lead is bonded to the sheet and the second lead is not bonded to the sheet in the step of bonding the sheet to the lead frame.

### BRIEF DESCRIPTION OF THE SEVERAL VIEWS OF THE DRAWING

FIG. 1A shows a lead frame and FIG. 1B shows a sheet according to a first embodiment of the present invention.

FIG. 2 is a diagram for illustrating a method of manufacturing a semiconductor device according to the first embodiment of the present invention.

FIG. 3 is a diagram for illustrating a method of manufacturing a semiconductor device according to the first embodiment of the present invention.

FIG. 4 is a diagram showing a semiconductor device according to the first embodiment of the present invention.

FIG. 5 is a diagram showing a circuit board according to the first embodiment of the present invention.

FIG. 6 is a diagram showing a sheet according to a second embodiment of the present invention.

FIG. 7 is a diagram showing a semiconductor device according to a third embodiment of the present invention.

FIG. 8 is a diagram showing a semiconductor device according to the third embodiment of the present invention.

FIG. 9 is a diagram showing a semiconductor device according to a fourth embodiment of the present invention.

FIG. 10 is a diagram showing a semiconductor device according to the fourth embodiment of the present invention.

FIG. 11 is a diagram showing a semiconductor device according to a fifth embodiment of the present invention.

FIG. 12 is a diagram showing a semiconductor device according to a sixth embodiment of the present invention.

FIG. 13 is a diagram showing a semiconductor device according to a seventh embodiment of the present invention.

FIG. 14 is a diagram showing a semiconductor device according to a modification of the seventh embodiment of the present invention.

FIG. 15A shows a lead frame and FIG. 15B shows a sheet according to an eighth embodiment of the present invention.

FIG. 16 shows an example of an electronic instrument according to one embodiment of the present invention.

FIG. 17 shows another example of an electronic instrument according to one embodiment of the present invention.

### DETAILED DESCRIPTION OF THE EMBODIMENT

An objective of the embodiments of the present invention is to improve the degrees of freedom of manufacture and reliability of a semiconductor device using a lead frame.

(1) According to one embodiment of the present invention, there is provided a semiconductor device comprising:

a semiconductor chip;

a sheet on which the semiconductor chip is mounted;

a sealing section in which the semiconductor chip and the sheet are sealed; and

a plurality of leads electrically connected to the semiconductor chip by wires within the sealing section,

wherein the leads include a first lead which is bonded to the sheet and a second lead which is not bonded to the sheet.

In this semiconductor device, the semiconductor chip is mounted on the sheet which is bonded to the first lead, so that semiconductor chips of any size can be mounted by changing the size of the sheet. Therefore, time and cost required to manufacture various lead frames for semiconductor chips having different external shapes can be saved, whereby the degrees of freedom of manufacturing a semiconductor device can be increased.

Moreover, since the sheet is bonded to the first lead and is not bonded to the second lead, the sheet can be made smaller than the case in which the sheet is bonded to all the leads. Therefore, when the sheet is formed of an organic material, for example, the moisture content of the sheet in the sealing section can be reduced, improving reliability of the semiconductor device.

(2) In this semiconductor device, the sheet may be bonded to the first lead on a surface opposite to a surface on which the wires are provided.

(3) In this semiconductor device, the sheet may be bonded to the first leads on a surface on which the wires are provided.

(4) In this semiconductor device, the semiconductor chip may overlap with end portions of the leads; and the wires may be electrically connected to the leads at positions close to the end portions.

In this case, a semiconductor chip having a size so as to overlap with the end portions of the leads can be mounted.

(5) In this semiconductor device, the sheet may include a plurality of layers.

The layers enables to reinforce the sheet.

(6) In this semiconductor device, the sheet may include a core layer and an adhesive layer which is formed on the core layer.

The core layer enables to reinforce the sheet.

(7) In this semiconductor device, the sheet may have a shape approximately point-symmetric with respect to the center of the semiconductor chip.

This sheet can uniformly support the semiconductor chip.

(8) In this semiconductor device, the sheet may include a plurality of elongated sections extending in different directions from a position under a center of the semiconductor chip.

(9) In this semiconductor device, the sheet may have a connecting section which connects the elongated sections at the position under the center of the semiconductor chip; and the connecting section may have a width larger than the width of any of the elongated sections.

Since the connecting section has a width larger than the width of any of the elongated sections, the semiconductor chip can be supported reliably.

(10) In this semiconductor device, the sheet may have a closed shape, having a center opening.

(11) In this semiconductor device, the sheet may have a plurality of projecting sections provided on the periphery of the sheet having a closed shape; and

the projecting sections may be respectively bonded to the first leads.

(12) In this semiconductor device, the semiconductor chip may have a rectangular shape; and the first leads may be respectively disposed near the midpoints of the sides of the rectangular semiconductor chip.

(13) This semiconductor device may further comprise:

a third lead which extends in the sealing section and is not electrically connected to any of the wires, the sheet being bonded to the first and third leads.

(14) According to another embodiment of the present invention, there is provided a circuit board on which is mounted the above semiconductor device.

(15) According to further embodiment of the present invention, there is provided an electronic instrument comprising the above semiconductor device.

(16) According to still another embodiment of the present invention, there is provided a method of manufacturing a semiconductor device comprising:

bonding a sheet to a lead frame including first and second leads;

mounting a semiconductor chip on the sheet;

electrically connecting the semiconductor chip to the first and second leads by wires; and

sealing the semiconductor chip and the sheet in,

wherein the first lead is bonded to the sheet and the second lead is not bonded to the sheet in the step of bonding the sheet to the lead frame.

In this semiconductor device, the semiconductor chip is mounted on the sheet which is bonded to the first lead, so that semiconductor chips of any size can be mounted by changing the size of the sheet. Therefore, time and cost required to manufacture various lead frames for semiconductor chips having different external shapes can be saved, whereby the degrees of freedom of manufacturing a semiconductor device can be increased.

Moreover, since the sheet is bonded to the first lead and is not bonded to the second lead, the sheet can be made smaller than the case in which the sheet is bonded to all the leads. Therefore, when the sheet is formed of an organic material, for example, the moisture content of the sheet in the sealing section can be reduced, improving reliability of the semiconductor device.

(17) In this method of manufacturing a semiconductor device, the sheet may be bonded to the first lead on a surface opposite to a surface on which the wires are provided.

(18) In this method of manufacturing a semiconductor device, the sheet may be bonded to the first leads on a surface on which the wires are provided.

(19) In this method of manufacturing a semiconductor device, the semiconductor chip may overlap with end portions of the leads; and the wires may be electrically connected to the leads at positions close to the end portions.

In this case, a semiconductor chip having a size so as to overlap with the end portions of the leads can be mounted.

(20) In this method of manufacturing a semiconductor device, the lead frame may further include a third lead which is not electrically connected to any of the wires; and the sheet may be bonded to the first and third leads.

Various embodiments of the present invention will be further described below with reference to the drawings. Note that the present invention is not limited to the following embodiments.

First Embodiment

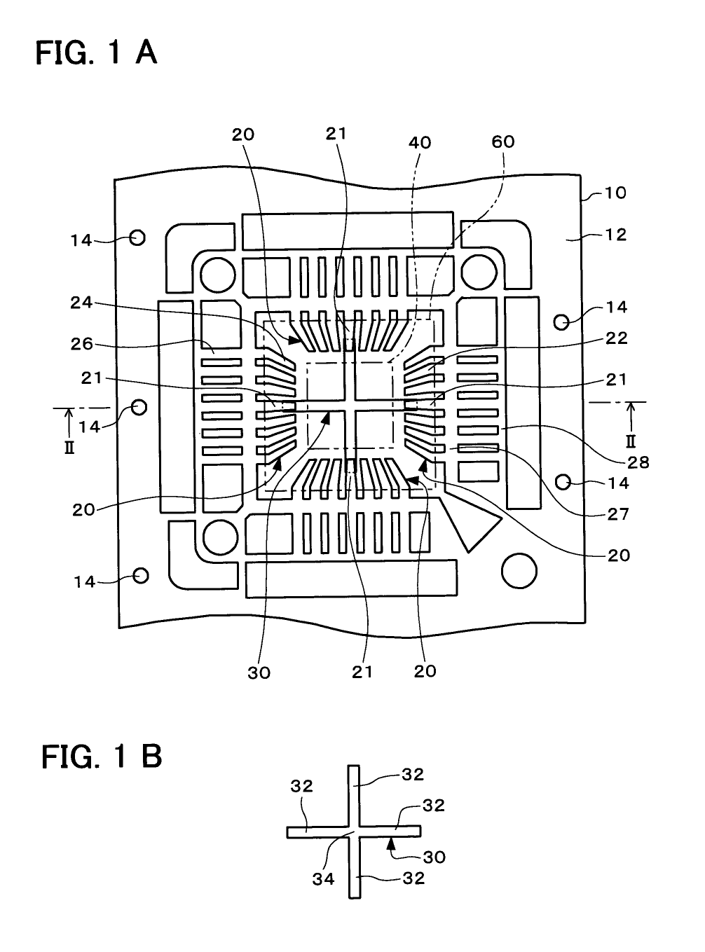

FIGS. 1A to 5 illustrate a first embodiment of the present invention. FIG. 1A shows a lead frame and FIG. 1B shows a sheet according to the first embodiment.

A lead frame 10 is formed by processing a copper-based or iron-based sheet material. As the processing method, chemical etching or mechanical punching is applied. The lead frame 10 includes an outer frame 12. The outer frame 12 is generally rectangular (upper and lower portions are omitted in FIG. 1A). The shape of the outer frame 12 corresponds to the external shape of the lead frame 10.

At least one hole (jig hole) 14 is formed in the outer frame 12. This enables the lead frame 10 to be easily positioned in molds (first and second sealing molds 50 and 52 (see FIG. 3), for example). A plurality of holes 14 may be formed on opposite ends of the outer frame 12. In this case, it is preferable that the hole 14 formed on one end (left end in FIG. 1A, for example) of the outer frame 12 and the hole 14 formed on the other end (right end in FIG. 1A, for example) of the outer frame 12 be formed at different positions in the longitudinal direction (vertical direction in FIG. 1A, for example) of the outer frame 12. This enables the lead frame 10 to be set in the molds in the right direction.

The lead frame 10 has a plurality of leads 20. The leads 20 are disposed around a semiconductor chip 40 represented by a dash-dot-dot line in FIG. 1A. In more detail, the leads 20 extend toward the semiconductor chip 40. For example, the leads 20 may extend toward each of four sides of the rectangular semiconductor chip 40. The leads 20 are sorted into a plurality of groups (four groups in FIG. 1A) by extending directions. As a modification example, the leads 20 may extend toward each of opposite two sides of the rectangular semiconductor chip 40.

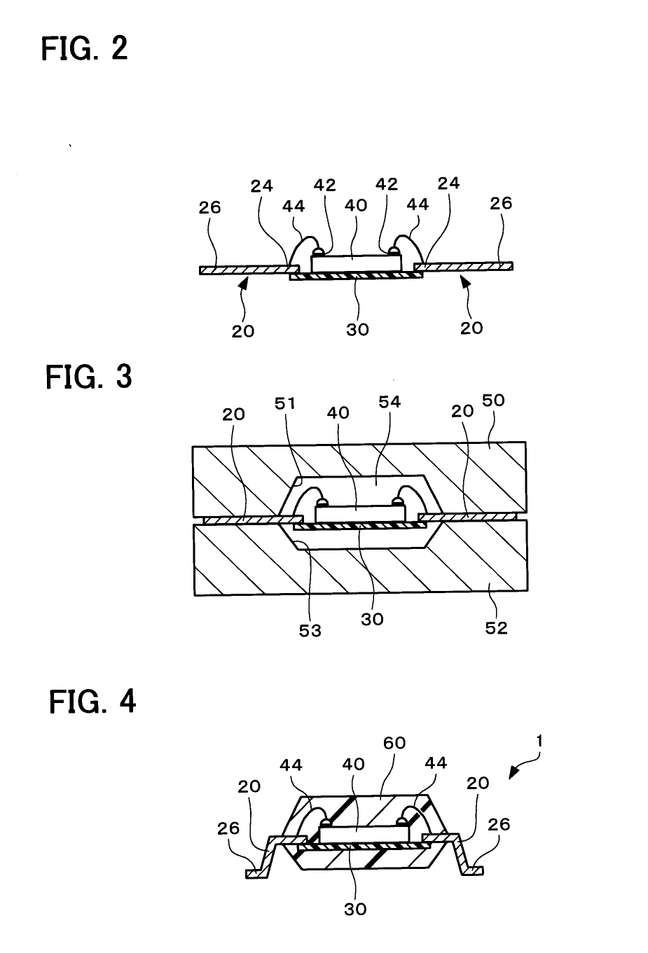

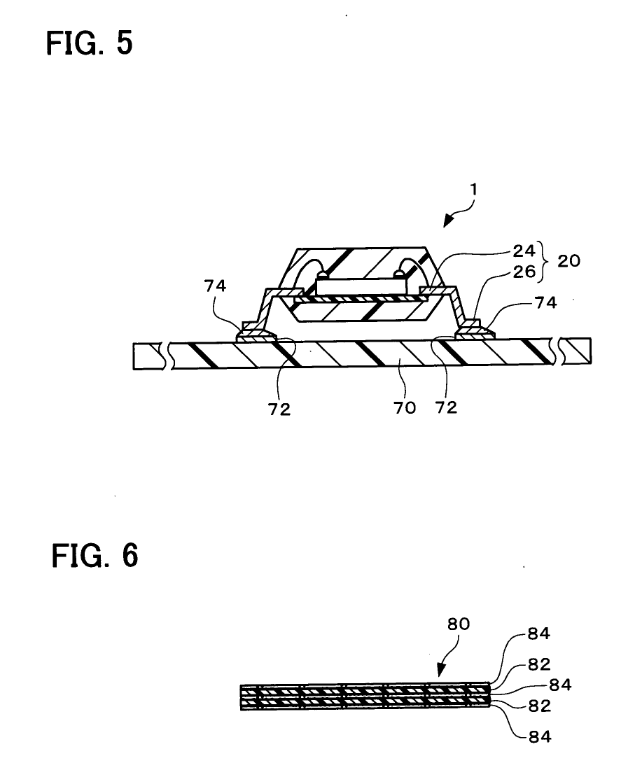

Each of the leads 20 includes an inner lead 24 and an outer lead 26. The inner lead 24 is electrically connected to the semiconductor chip 40 through a wire 44 (see FIG. 2), and sealed in a sealing section 60 indicated by a dash-dot-dot line. The outer lead 26 is exposed to outside from the sealing section 60, and is electrically connected to another electronic part (circuit board, for example) (see FIG. 5). The inner lead 24 or the outer lead 26 may be the end of the lead 20. As shown in FIG. 1A, the pitch of the inner leads 24 is smaller than the pitch of the outer leads 26. The lead 20 may extend horizontally, or the inner lead 24 may incline downward (or be downset).

The adjacent leads 20 are connected in this stage. In the example shown in FIG. 1A, the adjacent leads 20 are connected at a plurality of positions (two in FIG. 1A). The leads 20 are connected to the outer frame 12 of the lead frame 10.

A first connecting section 27 connects the middle of the leads 20. The first connecting section 27 is disposed outside the sealing section 60. The first connecting section 27 is called a dambar (or tie bar), and prevents a material for the sealing section 60 from leaking between the adjacent leads 20.

A second connecting section 28 connects end portions of the leads 20 (or outer leads) opposite to the semiconductor chip 40. The second connecting section 28 may be the end portions of the leads 20. The lead 20 can be prevented from being bent in the crosswise direction (or toward the adjacent lead) in a step of forming the leads 20 by providing the second connecting section 28, for example. Therefore, the adjacent leads 20 can be prevented from coming into contact with each other. The first and second connecting sections 27 and 28 are cut after a sealing step.

The lead frame 10 is used in the method of manufacturing a semiconductor device according to this embodiment. However, the form of the lead frame is not limited to the form of the lead frame 10.

As shown in FIG. 1A, a sheet 30 is bonded to the lead frame 10. The sheet 30 is preferably formed of an insulating material. This prevents occurrence of short circuits between the leads 20 or between the lead 20 and the semiconductor chip 40. The sheet 30 may be formed of an organic material (resin, for example) or an inorganic material (ceramic or glass, for example). The sheet 30 may be either a flexible substrate or a rigid substrate. The sheet 30 may be a single layer (see FIG. 2). The thickness of the sheet 30 is not limited.

The sheet 30 is bonded to first leads 21 among the leads 20. The first leads 21 are used to support the sheet 30. The sheet 30 may be bonded to the first leads 21 by providing an adhesive material to the sheet 30, or the sheet 30 may have an adhesive function. If the sheet 30 has an adhesive function, the bonding step is facilitated.

As shown in FIG. 1A, the leads 20 include the first leads 21 to which the sheet 30 is bonded, and second leads 22 to which the sheet 30 is not bonded. The first and second leads 21 and 22 may have the same form (shape, width, length, etc.). As a modification example, the first and second leads 21 and 22 may have different forms. For example, if the width of the first leads 21 is greater than the width of the second leads 22, the sheet 30 is easily bonded to the first leads 21.

As shown in FIGS. 1A and 2, the sheet 30 may be bonded to the first leads 21 on a surface opposite to a surface on which the wire 44 is formed. Specifically, the first leads 21 and the wires 44 are disposed on the same side (upper side in FIG. 2) with respect to the sheet 30. This allows the sheet 30 to be disposed at a position lower than the leads 20, whereby the distance between electrodes 42 of the semiconductor chip 40 and the leads 20 can be decreased. Therefore, since the length (or height) of the wires 44 can be decreased, a thin, high-speed semiconductor device can be manufactured.

The sheet 30 may be bonded to a plurality of first leads 21 (the number of the first leads 21 is four in FIG. 1A, but may be two). The first leads 21 are preferably disposed at positions approximately symmetrical (point-symmetric, for example) with respect to the center (or the center of gravity) of the semiconductor chip 40. This enables the semiconductor chip 40 to be mounted stably as described later. In the example shown in FIG. 1A, the first leads 21 are respectively disposed in or near the midpoints of the sides of the rectangular semiconductor chip 40. In more detail, the first leads 21 may be disposed near the center (or in the center, for example) in each group of the leads sorted by extending directions.

The shape of the sheet 30 may be determined taking into consideration the positions of the first leads 21, the external shape of the semiconductor chip 40, and the like. The sheet 30 may support a part of the semiconductor chip 40. It is preferable that the external shape (surface area or volume) of the sheet 30 be as small as possible. This prevents occurrence of failure (failure due to expansion or shrinkage of the sheet, for example) of the semiconductor device due to heat applied during the manufacturing step in the case where the materials differ between the sheet 30 and the sealing section 60, for example.

The sheet 30 may have a shape approximately symmetrical (point-symmetric, for example) with respect to the center (center of gravity) of the semiconductor chip 40. This enables the semiconductor chip 40 to be uniformly supported on the sheet 30. Therefore, the semiconductor chip 40 can be secured on the sheet 30 in a stable state.

The sheet 30 has a plurality of elongated sections 32 extending in different directions from the center (center of gravity) of the semiconductor chip 40. The elongated sections 32 are connected through a connecting section 34. The connecting section 34 is disposed at the center of the semiconductor chip 40. The width of the connecting section 34 may be the same as the width of elongated section 32. The width of the elongated section 32 may be either greater or smaller than the width of the lead 20 (first lead 21). The width of the elongated section 32 may be the same as the width of the lead 20. The angle formed by two elongated sections may be the same as the angle formed by the other two elongated sections.

In the example shown in FIG. 1B, the sheet 30 has four elongated sections 32 extending in four directions from the center of the semiconductor chip 40. In this case, the angles formed by the elongated sections may be 90°. Specifically, the sheet 30 is in the shape of a cross (letter “X”). As a modification example, the sheet may have two elongated sections extending in two directions from the center of the semiconductor chip 40, and the angles formed by the elongated sections may be 180°.

As shown in FIG. 2, a die bonding step is performed. In more detail, the semiconductor chip 40 is mounted on the sheet 30. FIG. 2 is a cross-sectional view taken along the line II-II of the lead frame in FIG. 1A, the outer frame 12 of the lead frame 10 being omitted.

The external shape of the semiconductor chip 40 is generally a rectangle. As a modification example, the external shape of the semiconductor chip 40 may be a circular shape or a polygonal shape other than a rectangle. An integrated circuit is formed on the semiconductor chip 40. The semiconductor chip 40 has at least one (two or more in many cases) electrode 42 which is electrically connected to the integrated circuit. The electrodes 42 may be disposed on the four or two sides of the semiconductor chip 40, or may be provided in the center of the semiconductor chip 40. The electrodes 42 are generally formed of an aluminum-based or copper-based metal. A passivation film (not shown) is formed on the semiconductor chip 40 so as to cover the electrodes 42 in an area other than the center. The passivation film may be formed of SiO₂, SiN, polyimide resin, or the like.

In the example shown in FIG. 2, the semiconductor chip 40 is disposed at the center surrounded by the leads 20. The semiconductor chip 40 may be disposed so as not to overlap with the leads 20. The semiconductor chip 40 may be bonded to the sheet 30 through an adhesive material, or directly bonded to the sheet 30 if the sheet 30 has an adhesive function.

A wire bonding step is then performed. In more detail, the electrodes 42 of the semiconductor chip 40 are electrically connected to the leads 20 (inner leads 24) through the wires 44. The wire 44 is a conductive wire (gold wire, for example). The wire bonding step may be performed by applying a ball bonding method. For example, the tip of the wire 44 pulled out from a tool (capillary, for example) is caused to melt in the shape of a ball, and is thermally bonded to the electrode 42. The wire 44 is then pulled toward the lead 20, and a part of the wire 44 is thermally bonded to the inner lead 24 by using the tool. It is preferable to apply ultrasonic vibration in combination with heat during thermal bonding. In the case of bonding the wire 44 to the electrode 42 before bonding the wire 44 to the inner lead 24, a bump is formed on the electrode 42 as shown in FIG. 2. The wire 44 may be bonded to the inner lead 24 of the lead 20 before bonding the wire 44 to the electrode 42. In this case, a bump is formed on the inner lead 24.

As shown in FIG. 3, a sealing step (molding step, for example) is performed. In this embodiment, the first and second molds 50 and 52 are used. In the example shown in FIG. 3, the first mold 50 is an upper mold (upper die) on the side of the semiconductor chip 40, and the second mold 52 is a lower mold (lower die) on the side of the sheet 30. Recess sections 51 and 53 are respectively formed in the first and second molds 50 and 52. A cavity 54 is formed by closing the first and second molds 50 and 52. The cavity 54 is filled with a sealing material (resin, for example) to seal the sheet 30, the semiconductor chip 40, the wires 44, and the inner leads 24. It is preferable that the sheet 30 support the semiconductor chip 40 so that the semiconductor chip 40 is not tilted due to flow of the sealing material. The semiconductor chip 40 can be prevented from being tilted by forming the sheet 30 in the shape of a cross (letter X) as illustrated in this embodiment, for example.

The sealing section 60 is thus formed. The leads 20 protrude from the sealing section 60. The outer leads 26 are exposed to outside from the sealing section 60.

A lead forming step is then performed. The bending shape of the leads 20 is not limited. As shown in FIG. 4, the leads 20 may be formed in a surface-mount type bending shape. Specifically, the leads 20 are formed so that the surface of the outer leads 26 extends in parallel to the mounting surface of the circuit board or the like. For example, the leads 20 may be bent in the shape of a gull wing. The forming step may be performed by using a die, roller, punch, or the like. As a modification example, the leads 20 may be formed in a through-hole-mount type bending shape so that the surface of the outer leads 26 extends perpendicularly to the mounting surface of the circuit board or the like.

A burr removal step, a coating (plating) step, a trimming step, a marking step, and the like may be performed either before or after the forming step. For example, burrs of the sealing section 60 may be removed after the sealing step by cutting the first connecting section 27 (dambar cutting) as the trimming step. Burrs of the sealing section 60 may be removed at the same time when cutting the first connecting section 27. The coating step of the lead frame 10 is then performed. A metal film (not shown) is formed on the lead frame 10 by electroplating in an area exposed from the sealing section 60. If the leads 20 are connected to the outer frame 12, the leads 20 can be electroplated through the outer frame 12. The leads 20 are then cut off from the outer frame 12. In this case, the forming step of the leads 20 may be performed in a state in which the adjacent leads 20 are connected through the second connecting section 28. The second connecting section 28 is cut after the forming step. An inspection step is then performed to obtain a semiconductor device 1.

The semiconductor device according to this embodiment includes the leads 20, the sheet 30, the semiconductor chip 40, and the sealing section 60. The leads 20 protrude from the sealing section 60 and are electrically connected to the semiconductor chip 40 through the wires 44 inside the sealing section 60. The sheet 30 is bonded to a part (first leads 21) of the leads 20. Specifically, the sheet 30 is not supported on all of the leads 20, but is supported on the first leads 21. The form of the sheet 30 is the same as described above. The semiconductor chip 40 is mounted on the sheet 30.

In FIG. 5, the semiconductor device according to this embodiment is mounted on a circuit board. A circuit board 70 may be a motherboard. An organic substrate is generally used as the circuit board 70. A desired interconnecting pattern 72 is formed of copper or the like on the circuit board 70. The outer leads 26 of the leads 20 of the semiconductor device 1 are electrically connected to the interconnecting pattern 72. For example, the outer leads 26 may be bonded to the interconnecting pattern 72 by a soldering or brazing material (solder, for example) 74.

The semiconductor device according to this embodiment includes a configuration derived from any of the specific items selected from the above manufacturing method. The semiconductor device according to this embodiment has the above-described effects. The semiconductor device according to this embodiment includes a semiconductor device manufactured by the above manufacturing method.

According to this embodiment, the semiconductor chip 40 is mounted on the sheet 30 bonded to the first leads 21. Therefore, the semiconductor chips 40 in various sizes can be mounted by merely adjusting the size of the sheet 30. Therefore, time and cost necessary for manufacturing the lead frames 10 corresponding to different external shapes of the semiconductor chips 40 can be saved, whereby the degrees of freedom of the manufacture of the semiconductor device can be increased.

Moreover, since the sheet 30 is bonded to the first leads 21, the sheet 30 can be made smaller than in the case of bonding the sheet 30 to all the leads 20. Therefore, in the case where the sheet 30 is formed of an organic material, the moisture content in the sheet 30 inside the sealing section 60 can be reduced, whereby reliability of the semiconductor device can be improved.

Furthermore, the area of the lead frame (metal) is decreased since a die pad is not formed. This increases adhesion between the sealing section 60 and the lead frame, whereby heat resistance of the semiconductor device can be improved.

The present invention is not limited to this embodiment and can be applied to various other embodiments. In the following embodiments, description of items common to other embodiments (configuration, effects and functions) and things which could be assumed from other embodiments are omitted. The present invention also includes things which could be achieved by combining the embodiments.

Second Embodiment

FIG. 6 is a sectional view of a sheet for illustrating a second embodiment of the present invention. In this embodiment, a sheet 80 is made up of a plurality of layers.

The sheet 80 includes core layers 82 and adhesive layers (layers formed of an adhesive material) 84 formed on the surfaces of the core layers 82. The core layer 82 may be formed of either an organic material (resin, for example) or an inorganic material (ceramic or glass, for example). The core layer 82 may be formed of a conductive material (metal, for example). The core layer 82 may be either a flexible substrate or a rigid substrate. The sheet 80 can be reinforced by providing the core layer 82.

The adhesive layer 84 may be used to bond a plurality of core layers 82, or used to bond the sheet 80 to the first leads 21 or the semiconductor chip 40. In the case where the sheet 80 includes only one core layer 82, the adhesive layer 82 is formed on either one side or both sides of the core layer 82.

A plurality of core layers 82 (two in FIG. 6) may be stacked. In this case, the adhesive layer 84 is formed between the core layers 82. The adhesive layer 84 may be formed on both sides of a laminate consisting of the core layers 82 as shown in FIG. 6, or formed on one side of the laminate.

According to this embodiment, since the sheet 80 is made up of a plurality of layers, the sheet 80 can be reinforced, whereby the semiconductor chip 40 can be secured stably.

Third Embodiment

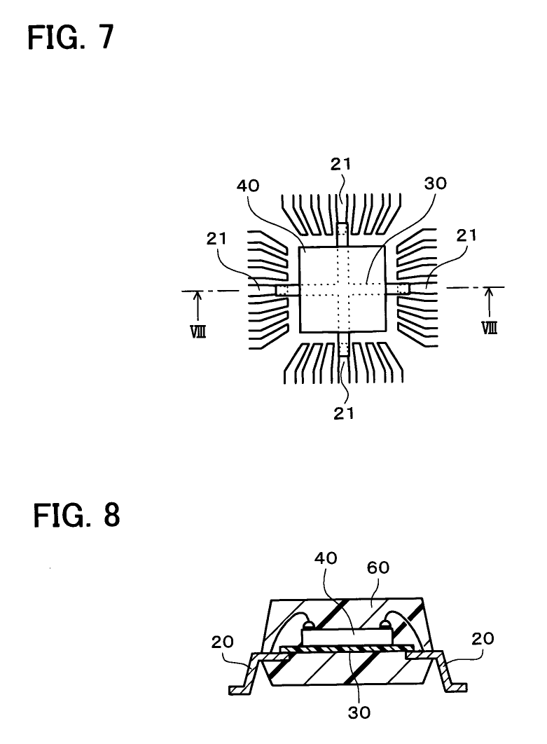

FIGS. 7 and 8 are diagrams for illustrating a third embodiment of the present invention. FIG. 7 is a partial plan view of a semiconductor device, and FIG. 8 is a cross-sectional view taken along the line VIII-VIII of the semiconductor device in FIG. 7. In this embodiment, the sheet 30 is bonded to the first leads 21 on a surface on which the wires 44 are formed. In other words, one side of the sheet 30 is bonded to the semiconductor chip 40 and the other side of the sheet 30 is bonded to the first lead 21.

The sheet 30 is bonded to the first leads 21 so as to avoid the bonding region of the wires 44. As shown in FIG. 8, the sheet 30 is bonded to the end portions of the first leads 21, and the wires 44 are bonded to the first leads 21 in an area other than the end portions (or near the end portions, for example). In the example shown in FIGS. 7 and 8, the semiconductor chip 40 is disposed so as not to overlap with the leads 20 (including the first leads 21).

Fourth Embodiment

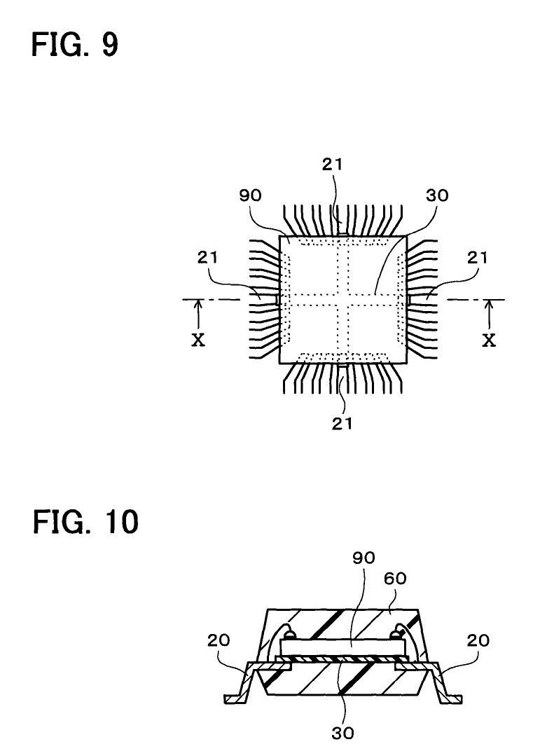

FIGS. 9 and 10 are diagrams for illustrating a fourth embodiment of the present invention. FIG. 9 is a partial plan view of a semiconductor device, and FIG. 10 is a cross-sectional view taken along the line X-X of the semiconductor device in FIG. 9. In this embodiment, a semiconductor chip 90 overlaps with the end portions of the leads 20. The other configuration is the same as the configuration in the third embodiment.

The external shape of the semiconductor chip 90 is larger than the center region surrounded by the leads 20. However, according to this embodiment, it is unnecessary to redesign the lead frame. Specifically, the sheet 30 is bonded to the first leads 21, and the semiconductor chip 90 is mounted on the sheet 30 on the side opposite to the first leads 21. Therefore, the semiconductor chip 90 can be prevented from coming into contact with the leads 20. It is preferable that the sheet 30 have a thickness sufficient to prevent the semiconductor chip 90 from coming into contact with the leads 20.

According to this embodiment, the semiconductor chip 90 having a size so as to overlap with the end portions of the leads 20 can be mounted.

Fifth Embodiment

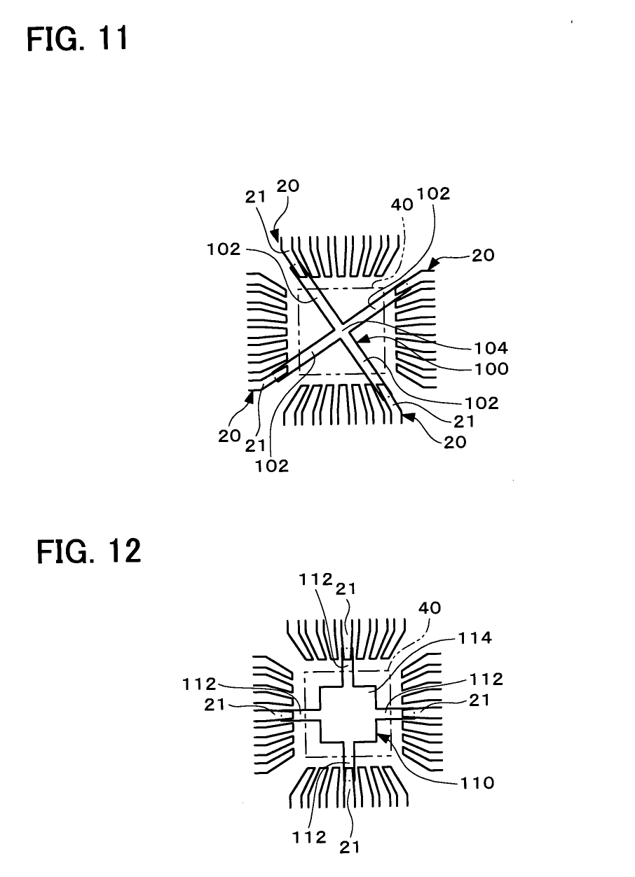

FIG. 11 is a diagram showing a sheet according to a fifth embodiment of the present invention. This embodiment differs from the first embodiment in the positions of the first leads 21.

The description in the first embodiment can be applied to the form of the leads 20 excluding the positions of the first leads 21. Specifically, the leads 20 are divided into a plurality of groups (four in FIG. 11) extending in different directions. The first leads 21 are disposed near the end portions (outermost ends, for example) of each group of the leads. As shown in FIG. 11, the first leads 21 are preferably disposed at positions approximately symmetrical (point-symmetric, for example) with respect to the center (center of gravity) of the semiconductor chip 40.

A sheet 100 has four elongated sections 102 extending in four directions from the center of the semiconductor chip 40. The elongated sections 102 are connected through a connecting section 104. The sheet 100 may be in the shape of a cross (letter X), and the angles formed by the elongated sections may be 90° in the same manner as in the sheet 30 described in the first embodiment.

According to this embodiment, the semiconductor chip 40 can be uniformly supported on the sheet 100 so that the semiconductor chip 40 is not tilted.

The sheet 100 may be bonded to either side (the side of the wire or the side opposite thereto) of the first lead 21. This also applies to the following embodiments.

Sixth Embodiment

FIG. 12 is a diagram showing a sheet according to a sixth embodiment of the present invention. In this embodiment, a sheet 110 has a plurality of elongated sections 112 and a connecting section 114. The width of the connecting section 114 is greater than the width of the elongated section 112. The description in the first embodiment can be applied to the description of the elongated section 112 and the connecting section 114 as far as possible.

The external shape of the connecting section 114 may be a rectangle (or a square of about 4×4 mm, for example) as shown in FIG. 12, or may be a circular shape or a polygonal shape other than a rectangle. The connecting section 114 may be smaller than the semiconductor chip 40 as shown in FIG. 12, or larger than the semiconductor chip 40.

In this embodiment, since the width of the connecting section 114 is greater than the width of the elongated section 112, the semiconductor chip 40 can be supported securely.

Seventh Embodiment

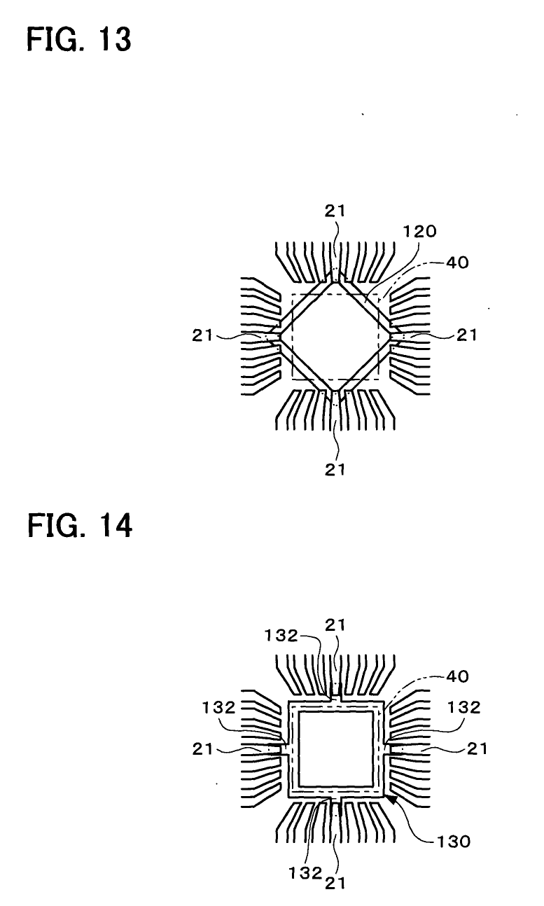

FIGS. 13 and 14 are diagrams respectively showing a sheet according to a seventh embodiment of the present invention. In this embodiment, a sheet has a closed shape.

As shown in FIG. 13, a sheet 120 has a shape having a center opening. An external shape and an inner shape (or a shape of the opening) of the sheet 120 are not limited, and may be either rectangular or circular. The external shape of the sheet 120 may be similar to and a little larger than the inner shape of the sheet 120. The sheet 120 may have a polygonal closed shape as shown in FIG. 13, or a ring shape as a modification example.

The sheet 120 is bonded to the first leads 21 at the corners of the polygonal closed shape (or a rectangular closed shape, for example). As viewed in FIG. 13, the sheet 120 may be rotated at an angle of 45° with respect to the semiconductor chip 40. If the inner line of the sheet 120 is partially present outside the semiconductor chip 40 and a space from which the material for the sealing section enters is provided, adhesion of the sealing section is increased.

FIG. 14 is a diagram showing a modification of this embodiment. A sheet 130 includes a plurality of projecting sections 132 provided on the periphery of the sheet 130 of a closed shape. The projecting sections 132 are used to bond the sheet 130 to the first leads 21. The positions of the projecting sections 132 may be determined depending on the positions of the first leads 21. The projecting sections 132 enables the sheet 130 to be easily bonded to the first leads 21 irrespective of the shape of the sheet 130. In the example shown in FIG. 14, the outer periphery of the semiconductor chip 40 is positioned between the outer periphery and the internal line the sheet 130. Specifically, the sheet 130 supports the outer edge of the semiconductor chip 40.

Eighth Embodiment

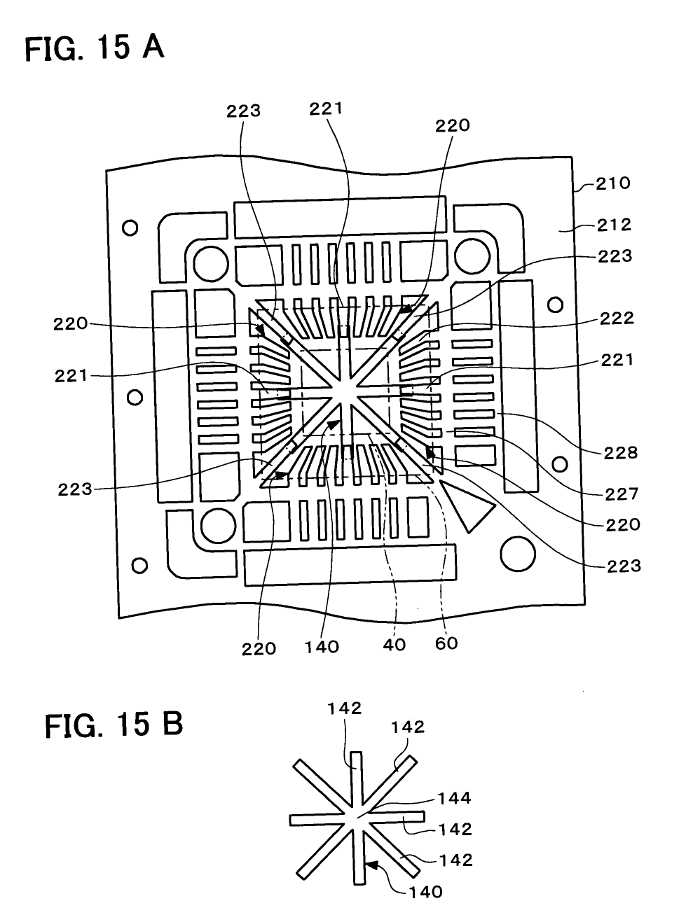

FIGS. 15A and 15B are diagrams for illustrating an eighth embodiment of the present invention. FIG. 15A shows a lead frame and FIG. 15B shows a sheet used in this embodiment. A form of the lead frame differs from the above description in this embodiment.

A lead frame 210 includes a plurality of leads 220 (first and second leads 221 and 222) and at least one third lead 223. The leads 220 are subjected to wire bonding and are the same as the leads described in the first embodiment. The third lead 223 is supported on an outer frame 212 and extends inside the sealing section 60 indicated by a dash-dot-dot line beyond the edge of the sealing section 60. The third lead 223 extends toward the semiconductor chip 40. As shown in FIG. 15A, the third lead 223 is not required to overlap with the semiconductor chip 40. As a modification example, the third lead 223 may extend toward the semiconductor chip 40 and overlap with the semiconductor chip 40.

As shown in FIG. 15A, in the case where the leads 220 are divided into a plurality of groups (four in FIG. 15A) extending in different directions, the third leads 223 may be disposed between the adjacent groups. The third leads 223 may extend toward the corners of the rectangular semiconductor chip 40.

The third lead 223 is used to support the sealing section 60 on the outer frame 212. This enables the sealing section 60 to be handled together with the lead frame 210 even after first and second connecting sections 227 and 228 are cut.

A wire is not bonded to the third lead 223. Specifically, the third lead 223 refers to a lead which is not electrically connected to the semiconductor chip 40. The third lead 223 may be formed of a material either the same as or different from the material for the lead frame 210.

In this embodiment, the sheet 140 is bonded to the first and third leads 221 and 223. In this case, the sheet 140 may be bonded to all or part of the third leads 223. The sheet 140 may be bonded to the third lead 223 on the side opposite to the semiconductor chip 40 as shown in FIG. 15A, or bonded to the third lead 223 on the side of the semiconductor chip 40.

The shape of the sheet 140 may be determined taking into consideration the positions of the first and third leads 221 and 223 and the like. The sheet 140 includes a plurality of elongated sections 142 extending in different directions from the center (center of gravity) of the semiconductor chip 40, and a connecting section 144 which connects the elongated sections 142. In the example shown in FIG. 15B, the sheet 140 has eight elongated sections 142 extending in eight directions. The elongated sections 142 of the sheet 140 are bonded to four first leads 221 and four third leads 223. The description in the above embodiments can be applied to the details of the form of the sheet 140 as far as possible.

According to this embodiment, since the sheet 140 is also bonded to the third lead 223, the sheet 140 can be securely prevented from being removed from the leads due to flow of the material for the sealing section, for example.

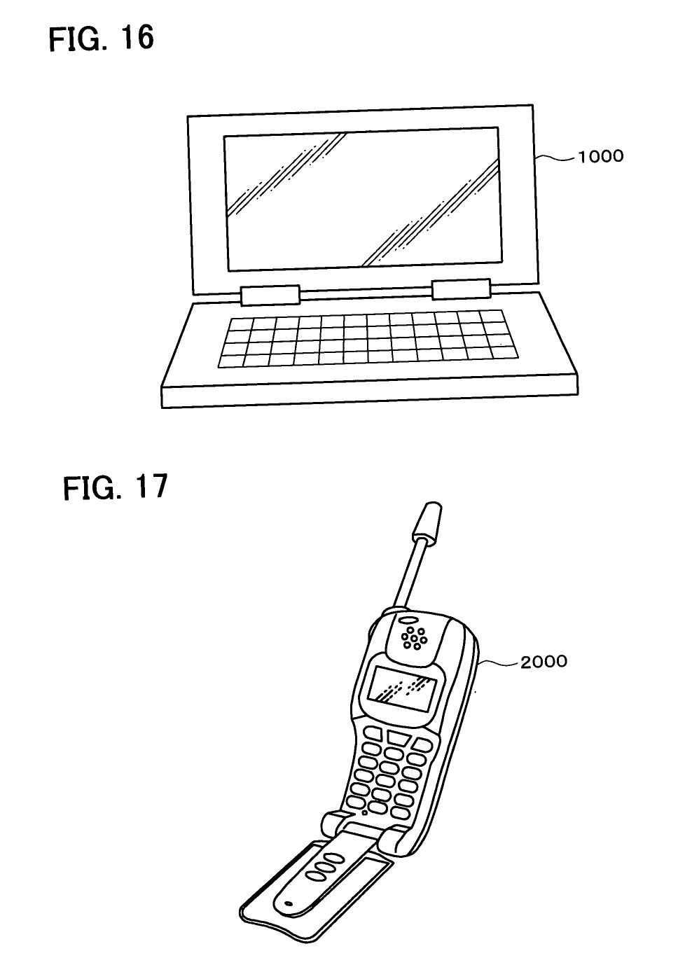

FIGS. 16 and 17 respectively show a notebook-type personal computer 1000 and a portable telephone 2000 as examples of an electronic instrument including the semiconductor device according to one embodiment of the present invention.

The present invention is not limited to the above-described embodiments, and various modifications can be made. For example, the present invention includes various other configurations substantially the same as the configurations described in the embodiments (in function, method and effect, or in objective and effect, for example). The present invention also includes a configuration in which an unsubstantial portion in the described embodiments is replaced. The present invention also includes a configuration having the same effects as the configurations described in the embodiments, or a configuration able to achieve the same objective. Further, the present invention includes a configuration in which a publicly known technique is added to the configurations in the embodiments.

What is claimed is:

1. A semiconductor device comprising:
a semiconductor chip;
a sheet on which the semiconductor chip is mounted;
a sealing section in which the semiconductor chip and the sheet are sealed; and
a plurality of leads electrically connected to the semiconductor chip by wires within the sealing section,
wherein the leads include a first lead which is bonded to the sheet and a second lead which is not bonded to the sheet.

2. The semiconductor device as defined in claim 1,
wherein the sheet is bonded to the first lead on a surface opposite to a surface on which the wires are provided.

3. The semiconductor device as defined in claim 1,
wherein the sheet is bonded to the first leads on a surface on which the wires are provided.

4. The semiconductor device as defined in claim 3, wherein:
the semiconductor chip overlaps with end portions of the leads; and
the wires are electrically connected to the leads at positions close to the end portions.

5. The semiconductor device as defined in claim 1,
wherein the sheet includes a plurality of layers.

6. The semiconductor device as defined in claim 5,
wherein the sheet includes a core layer and an adhesive layer which is formed on the core layer.

7. The semiconductor device as defined in claim 1,
wherein the sheet has a shape approximately point-symmetric with respect to the center of the semiconductor chip.

8. The semiconductor device as defined in claim 1,
wherein the sheet includes a plurality of elongated sections extending in different directions from a position under the center of the semiconductor chip.

9. The semiconductor device as defined in claim 8, wherein:
the sheet has a connecting section which connects the elongated sections at the position under the center of the semiconductor chip; and
the connecting section has a width larger than the width of any of the elongated sections.

10. The semiconductor device as defined in claim 1,
wherein the sheet has a shape having a center opening.

11. The semiconductor device as defined in claim 10, wherein:
the sheet has a plurality of projecting sections provided on the periphery of the sheet having a closed shape; and
the projecting sections are respectively bonded to the first leads.

12. The semiconductor device as defined in claim 1, wherein:
the semiconductor chip has a rectangular shape; and
the first leads are respectively disposed near the midpoints of the sides of the rectangular semiconductor chip.

13. The semiconductor device as defined in claim 1, further comprising:
a third lead which extends in the sealing section and is not electrically connected to any of the wires,
wherein the sheet is bonded to the first and third leads.

14. A circuit board on which is mounted a semiconductor device including:
a semiconductor chip;
a sheet on which the semiconductor chip is mounted;
a sealing section in which the semiconductor chip and the sheet are sealed; and
a plurality of leads electrically connected to the semiconductor chip by wires within the sealing section,
wherein the leads include a first lead which is bonded to the sheet and a second lead which is not bonded to the sheet.

15. An electronic instrument comprising a semiconductor device which includes:
a semiconductor chip;
a sheet on which the semiconductor chip is mounted;
a sealing section in which the semiconductor chip and the sheet are sealed; and
a plurality of leads electrically connected to the semiconductor chip by wires within the sealing section,
wherein the leads include a first lead which is bonded to the sheet and a second lead which is not bonded to the sheet.

16. A method of manufacturing a semiconductor device comprising:
bonding a sheet to a lead frame including first and second leads;
mounting a semiconductor chip on the sheet;
electrically connecting the semiconductor chip to the first and second leads by wires; and
sealing the semiconductor chip and the sheet in,
wherein the first lead is bonded to the sheet and the second lead is not bonded to the sheet in the step of bonding the sheet to the lead frame.

17. The method of manufacturing a semiconductor device as defined in claim 16,
wherein the sheet is bonded to the first lead on a surface opposite to a surface on which the wires are provided.

18. The method of manufacturing a semiconductor device as defined in claim 16,
wherein the sheet is bonded to the first leads on a surface on which the wires are provided.

19. The method of manufacturing a semiconductor device as defined in claim 18, wherein:
the semiconductor chip overlaps with end portions of the leads; and
the wires are electrically connected to the leads at positions close to the end portions.

20. The method of manufacturing a semiconductor device as defined in claim 16, wherein:
the lead frame further includes a third lead which is not electrically connected to any of the wires; and
the sheet is bonded to the first and third leads.
